(19) United States
(12) Patent Application Publication
(10) Pub. No.: US 2018/0076372 A1
(43) Pub. Date: Mar. 15, 2018

(54) Contacts for Bi-Te-Based Materials and Methods of Manufacture

(71) Applicant: University of Houston System, Houston, TX (US)

(72) Inventors: Zhifeng Ren, Pearland, TX (US); Weishu Liu, Houston, TX (US)

(73) Assignee: University of Houston System, Houston, TX (US)

(21) Appl. No.: 15/565,700

(22) PCT Filed: Dec. 10, 2015
(86) PCT No.: PCT/US2015/065129

§ 371 Date: Oct. 11, 2017

Related U.S. Application Data
(60) Provisional application No. 62/150,686, filed on Apr. 21, 2015.

(51) Int. Cl. H01L 35/20; H01L 35/22; H01L 35/16; H01L 35/18; H01L 35/34; C01B 19/00

(52) U.S. Cl. CPC H01L 35/20; H01L 35/22; C01B 19/002; H01L 35/18; H01L 35/34; H01L 35/16

(57) ABSTRACT

Systems and methods of manufacturing thermoelectric devices comprising at least one electrical contact fabricated using hot-pressing to increase the bonding strength at the contact interface(s) and reducing the contact resistance. The hot pressed component may include a first and a second metallic layer each in contact with a thermoelectric layer, and where a contact resistance between the first metallic layer and the thermoelectric layer or between the second metallic layer and the thermoelectric layer is less than about 10 μΩ cm². When interlayers are employed in a thermoelectric device, first hot pressed contact interface is formed between the thermoelectric layer and the first interlayer and a second hot pressed contact interface is formed between the thermoelectric layer and the second interlayer, and at least one of the first and the second hot pressed contact interfaces comprises a bonding strength of at least 16 MPa.

### CROSS-REFERENCE TO RELATED APPLICATIONS

This application is a 35 U.S.C. § 371 national stage application of PCT/US2015/065129 filed Dec. 10, 2015, which claims priority to U.S. Provisional Application No. 62/150,686 filed Apr. 21, 2015, entitled “Contacts for Bi₂Te₃-Based Materials and Methods of Manufacture,” each of which are incorporated herein by reference in their entirety for all purposes.

### STATEMENT REGARDING FEDERALLY-SPONSORED RESEARCH OR DEVELOPMENT

This work is supported by “Solid State Solar Thermal Energy Conversion Center (S³TEC)”, an Energy Frontier Research Center funded by the U.S. Department of Energy, Office of Science, Office of Basic Energy Science under award number DE-SC0001299

### BACKGROUND

Over the past decades, thermoelectric materials have been extensively studied for potentially broad applications in refrigeration, waste heat recovery, solar energy conversion, etc. The efficiency of thermoelectric devices is governed by the materials' dimensionless figure of merit ZT=(S²σ/κ)T, where S is the Seebeck, σ is the electrical conductivity, T is the absolute temperature, and κ is the thermal conductivity, respectively.

Chalcogenides may be employed in thermoelectric applications, and toxicity concerns in both manufacture and use of these materials have encouraged the study of lead-free chalcogenides. Bi₂Te₃-based materials have a history of use for the thermoelectric cooling applications. However, these materials have historically had challenges with respect to being able to have a reliable contact for use in power generating applications to harvest low-grade heat waste.

### BRIEF SUMMARY OF THE DISCLOSURE

In an embodiment, a thermoelectric device comprising: a hot-pressed component comprising: a first metallic layer in contact with a first thermoelectric layer; a second metallic layer in contact with the first thermoelectric layer; wherein at least one of a contact resistance between the first metallic layer and the first thermoelectric layer and a contact resistance between the second metallic layer and the first thermoelectric layer is less than about 10 μΩ cm².

In another embodiment, a thermoelectric device comprising: a hot-pressed component comprising: a first metallic layer in contact with a first interlayer; a thermoelectric layer in contact with the first interlayer and a second interlayer; and a second metallic layer in contact with the second interlayer, wherein the thermoelectric layer is disposed between the first and the second metallic layers, and wherein at least one hot pressed contact interface comprises a bonding strength of at least 16 MPa.

### BRIEF DESCRIPTION OF THE DRAWINGS

For a detailed description of the exemplary embodiments disclosed herein, reference will now be made to the accompanying drawings in which:

FIGS. 1A-1F are images of of contact interfaces made by directly hot pressing the Ni powders and TE powders together in various combinations according to certain embodiments of the present disclosure.

FIGS. 2A and 2B are SEM-EDS composition profiles between of the Ni/Bi_{0.4}Sb_{1.6}Te₃ interface and the Ni/Bi₂Te_{2.7}Se_{0.3} interface obtained from selected area SEM-EDS.

FIG. 3 is an XRD spectra of Ni+Bi₂Te_{2.7}Se_{0.3} (20 wt. % Ni), Ni+Bi_{0.4}Sb_{1.6}Te₃ (20 wt. % Ni), and NiTe.

FIG. 4 is a composition profile of Ni/NiTe/Bi₂Te_{2.7}Se_{0.3}, made by directly hot pressing at 500° C. for 2 min.

FIGS. 5A-5E illustrate the TEM images and EDS compositions of selected points at the Ni/Bi₂Te_{2.7}Se_{0.3} interface.

FIGS. 6A and 6B illustrate the temperature dependence of the Seebeck coefficient and the electrical resistivity of thermoelectric materials fabricated according to certain embodiments of the present disclosure.

FIG. 7 shows the composition dependent electrical resistivity and Seebeck coefficient for the formula of Bi₂(Te_{0.9}Se_{0.1})_{3-δ} fabricated according to certain embodiments of the present disclosure.

FIGS. 8A-8D illustrate temperature-dependent properties of thermoelectric materials fabricated according to embodiments of the present disclosure.

FIGS. 9A-9D are contour maps of electrical resistivity (FIG. 9A), Seebeck coefficient (FIG. 9B), and maps of the major carriers (FIG. 9C) and the major defect (FIG. 9D) as a function of composition of thermoelectric materials fabricated according to certain embodiments of the present disclosure.

FIG. 10, a schematic figure of a plurality of regions of a material before and after hot-pressing associated with high contact resistance observed during a probe scanning measurement.

FIGS. 11A-11C are SEM images and a voltage configuration associated with the probe scanning measurement.

FIG. 12 is a graph illustrating the contact resistance measurement made by the scanning probe measurement of thermoelectric legs fabricated according to certain embodiments of the present disclosure.

FIGS. 13A and 13B illustrate the contact resistance measurement and the efficiency measurements for two n-type legs with barrier layers fabricated according to certain embodiments of the present disclosure.

FIG. 14 is a graph of the contact resistance as a function of the hot pressing temperature for Ni/BTSS, Ni/BL-2/BTSS, and Ni/BTSS-HT-1d. BTSS: Bi₂Te_{2.7}Se_{0.3}S_{0.01} fabricated according to certain embodiments of the present disclosure.

FIG. 15 is a graph of the contact resistance as a function of hot-pressing temperature for thermoelectric materials fabricated according to embodiments of the present disclosure.

FIG. 16 is an SEM image of an interface of Ni hot pressed with a thermoelectric material fabricated according to embodiments of the present disclosure.

FIGS. 17A and 17B illustrate the contact resistance of a sample fabricated according to certain embodiments of the present disclosure before and after thermal cycling the sample.

FIGS. 18A and 18B illustrate the contact resistance of pure nickel (Ni) before and after thermal cycling the sample.

FIG. 19 is an illustration of an embodiment of a thermoelectric leg fabricated according to certain embodiments of the present disclosure.

FIGS. 20A and 20B are cross-sections of alternate embodiments of a thermoelectric leg fabricated according to certain embodiments of the present disclosure.

FIG. 21 is a method of fabricating thermoelectric devices according to certain embodiments of the present disclosure.

FIG. 22 is a flow chart of another method 2200 of fabricating thermoelectric devices according to certain embodiments of the present disclosure.

### DETAILED DESCRIPTION OF THE DISCLOSED EXEMPLARY EMBODIMENTS

The following discussion is directed to various exemplary embodiments. However, one of ordinary skill in the art will understand that the examples disclosed herein have broad application, and that the discussion of any embodiment is meant only to be exemplary of that embodiment, and not intended to suggest that the scope of the disclosure, including the claims, is limited to that embodiment.

The drawing figures are not necessarily to scale. Certain features and components herein may be shown exaggerated in scale or in somewhat schematic form and some details of conventional elements may not be shown in interest of clarity and conciseness.

In the following discussion and in the claims, the terms “including” and “comprising” are used in an open-ended fashion, and thus should be interpreted to mean “including, but not limited to . . . .”

Thermoelectric (TE) materials are useful for power generation and/or cooling applications because of the electric voltage that develops when a temperature differential is created across the material. TE cooling systems operate on the principal that a loop (circuit) of at least two dissimilar materials can pass current, absorbing heat at one end of the junction between the materials and releasing heat at the other end of the junction, and TE power generators enable the direct conversion from heat to electricity. As such, TE materials may be fabricated so that, when heat is applied to a portion of the TE material, the electrons migrate from the hot end towards a “cold” end, e.g., a portion of the TE material where heat is not being applied. The electrical current created when the electrons migrate may be harnessed for power, and the amount of electrical current (and resultant power generated) increases with an increasing temperature difference from the hot side of the TE material to the cold side. However, when a TE material is heated up, if it is heated for a long enough time period, held at a temperature over a time period, and/or heated to a high enough temperature, the cold side may actually heat up, so the thermoelectric devices in which the TE materials are employed may also use various methods to pull heat away from the cold side.

In an embodiment, materials for thermoelectric generators are fabricated to possess high dimensionless figure of merit ZT=[S²σ/(κₑ+κ_{L})]T, where S, σ, κₑ, κ_{L}, and T are the Seebeck coefficient, electrical conductivity, electronic thermal conductivity, lattice thermal conductivity, and absolute temperature, respectively. The thermoelectric effect is a combination of phenomenon including the Seebeck effect, Peltier effect, and Thomson effect. The Seebeck coefficient is associated with the Seebeck effect, which is the name of the effect observed when an electromagnetic effect is created when a structure (loop) is heated on one side. The Peltier effect is the term used to explain heating or cooling at a junction between two different TE materials when a current is generated in a circuit or other loop comprising the two different TE materials. The Thomson effect occurs when a Seebeck coefficient is not constant at a temperature (depending upon the TE material), so when an electric current is passed through a circuit of a single TE material that has a temperature gradient along its length, heat may be absorbed, and the temperature difference may be redistributed along the length when the current is applied. Thus, higher ZT values for TE materials across a variety of temperature ranges may continue to become increasingly valuable for applications at least across the fields of TE power generation and cooling. “Understanding of the Contact of Nanostructured Thermoelectric N-type Bi₂Te_{2.7}Se_{0.3} Legs for Power Generation Applications,” J. Mater. Chem. A, 2013, 1, 13093, which is incorporated in its entirety herein.

Fabrication Overview

A metallization layer such as nickel may be coupled to or disposed on one or both of the n- and p-type nanostructured legs using a sputtering method. However, sputtering is not a scalable method for mass production of such devices operating at temperature above 200° C., which may employ a thick nickel layer to prevent the Cu from the electrode and also Sn from solder diffusing into the thermoelectric materials. Electrochemical deposition processes may be employed to dispose a thicker nickel layer. However, the weak-bonding interface between nickel deposited by electrochemical deposition and the thermoelectric material (<10 MPa) leads to severe degradation in device efficiency. Since the power generation device operates at high temperature (about 250° C. in some embodiments) and larger temperature gradient (in some embodiments, from about 100 to about 200° C. mm⁻¹) than that of the cooling device (˜50° C. and 20˜30° C. mm⁻¹, respectively), stronger bonding strength is desirable between the Cu electrode and the thermoelectric elements.

In addition to the bonding strength, the electrical contact resistance between the electrode and thermoelectric materials needs to be minimized. The contact resistance R_{c} between the electrode and thermoelectric legs decreases the effective <ZT>_{D} of thermoelectric devices according to the formula,

$${〈 ZT 〉}_{D} = \frac{( L )}{( L + 2 {R}_{c} σ )} {〈 ZT 〉}_{M} \qquad ( 1 )$$

where L is the length of the thermoelectric leg, R_{c} is the contact resistance, σ is the electrical conductivity of the thermoelectric leg, and <ZT>_{M} is the effective ZT of the thermoelectric material between Tₕ and T_{c}. For a typical device L˜1 mm, and σ˜10⁵ S m⁻¹, Rc should be much less than L/2σ˜10⁻⁸ Ω m² (10⁻⁴ Ω cm²). Ideally, the contact resistance should be less than 1 μΩ cm².

In order to achieve a high bonding strength at the Ni/TE interface, a Ni pressed powder layer was disposed in contact with a Bi₂Te₃ powder layer and hot pressed. A significantly improved bonding strength was obtained in both n-type Ni/Bi₂Te_{2.7}Se_{0.3} (˜20 MPa) and p-type Ni/Bi_{0.4}Sb_{1.6}Te₃ (˜30 MPa) legs. A very large contact resistance was observed in n-type Ni/Bi₂Te_{2.7}Se_{0.3} (˜210 μΩ cm²) even though the contact resistance for p-type Ni/Bi_{0.4}Sb_{1.6}Te₃ is less than 1 μΩ cm². The high contact resistance observed using materials fabricated according to embodiments of the present disclosure may be related to the interface reaction of Ni/Bi₂Te_{2.7}Se_{0.3}.

Identification of the Interface Microstructure

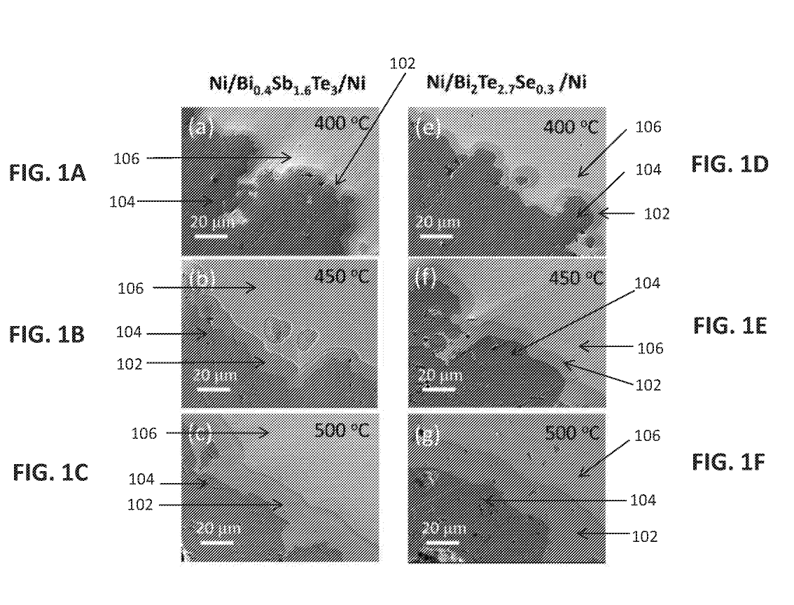

Referring now to FIGS. 1A-1F, FIG. 1A illustrates an interface of Ni/Bi_{0.4}Sb_{1.6}Te₃/Ni, hot pressed at about 400° C.; FIG. 1B illustrates an interface of Ni/Bi_{0.4}Sb_{1.6}Te₃/Ni, hot pressed at about 450° C.; FIG. 1C illustrates an interface of Ni/Bi_{0.4}Sb_{1.6}Te₃/Ni, hot pressed at about 500° C.; FIG. 1D illustrates an interface of Ni/Bi₂Sb_{2.7}Te₃/Ni, hot pressed at about 400° C.; FIG. 1E illustrates an interface of Ni/Bi₂Sb_{2.7}Te₃/Ni, hot pressed at about 450° C., FIG. 1F illustrates an interface of Ni/Bi₂Sb_{2.7}Te₃/Ni, hot pressed at 500° C. The dark region 104 identified in each figure comprises a nickel element, and the light region 106 is a thermoelectric element. FIGS. 1A-1C illustrate a BiSbTe thermoelectric element comprising Bi_{0.4}Sb_{1.6}Te₃, BiTeSe, and FIGS. 1D-1F illustrate a BiSbTe thermoelectric element comprising Bi₂Te_{2.7}Se_{0.3}, the TE elements are identified as “106” regardless of the composition in FIGS. 1A-1F.

FIGS. 1A-1F are images of cross-sections of microstructures of the contact region (between the Ni metallization layers 104 and thermoelectric (TE) elements 106 in both p-type legs Ni/Bi_{0.4}Sb_{1.6}Te₃/Ni and n-type legs Ni/Bi₂Te_{2.7}Se_{0.3}/Ni. The p and n-type legs were fabricated by directly hot pressing a Ni powder and TE powders. A layer (gray region 102) formed at the interface between the Ni (dark region 104) and TE (light region 106) during hot-pressing in both of n-type and p-type legs. Here, the layer 102 is referred to as an interface reaction layer (IRL) 102. In an embodiment, the thickness of the IRL 102 in n-type legs is about 4 μm for the sample hot pressed at 400° C. as shown in FIG. 1E, which is slightly thicker than that in p-type leg, which is about 3 μm, hot pressed at 400° C. as shown in FIG. 1A. When the hot pressing temperature from 400° C. to 500° C., as shown in FIGS. 1C and 1F, the thickness of the IRL also increased from about 3 μm to from about 13 μm to about 16 μm for the p-type leg (FIG. 1C), and from about 4 μm to from about 17 μm to about 21 μm for the n-type leg (FIG. 1F).

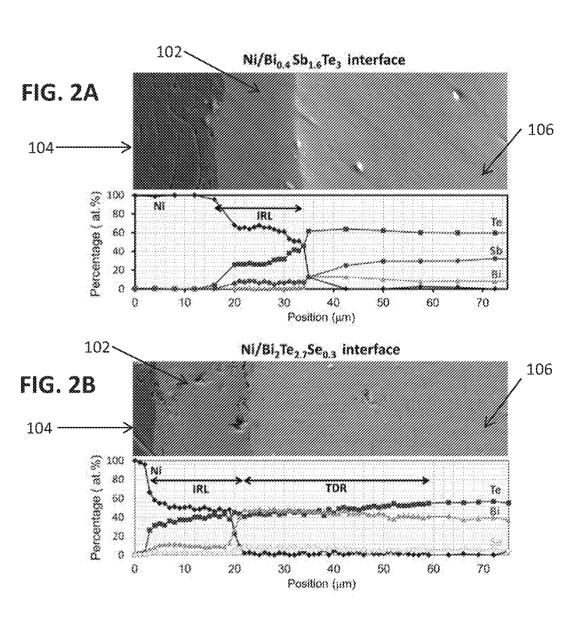

FIGS. 2A and 2B illustrate a partial selected area scan (˜2×20 μm²) using SEM-EDS of the interface IRLs for both p- and n-type leg samples from FIGS. 1C and 1F, respectively, to detect the atomic composition profile crossing from Ni side to thermoelectric materials side. From the Ni concentration profile it seems that a thicker Ni₃Te₂ and a thinner NiTe were formed at Ni/Bi_{0.4}Sb_{1.6}Te₃ interface (FIG. 2A), while a thinner Ni₃Te₂ and a thicker NiTe were formed at Ni/Bi₂Te_{2.7}Se_{0.3} interface (FIG. 2B). After the IRL region, a significantly thicker Te-deficient region (TDR) was observed in Ni/Bi₂Te_{2.7}Se_{0.3} samples (FIG. 2B), whereas stoichiometric Bi_{0.4}Sb_{1.6}Te₃ was observed right after the IRL in Ni/Bi_{0.4}Sb_{1.6}Te (FIG. 2A). The formation of a TDR suggested that the interfacial reaction consumes more of the chalcogen element in the n-type leg than the interfacial reaction in the p-type leg.

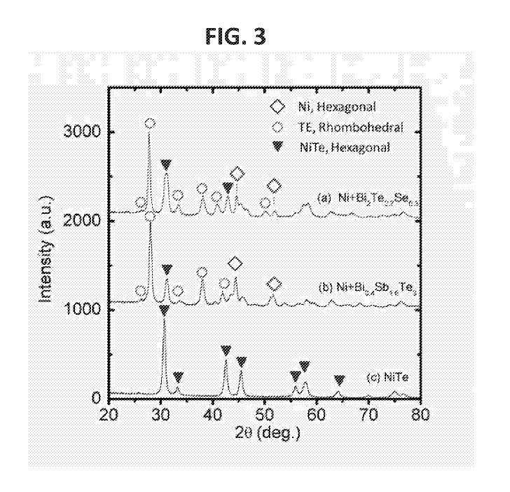

FIG. 3 illustrates x-ray diffraction (XRD) patterns for NiTe, Ni/Bi₂Te_{2.7}Se_{0.3}, and Ni/Bi_{0.4}Sb_{1.6}Te₃. In an embodiment, a reaction product may form at the region of the interface between nickel or other metal deposited by electrochemical deposition and the thermoelectric material. In order to confirm this reaction product, 20 wt. % Ni was mixed with 80 wt. % thermoelectric (TE) powders of both p- and n-type and each mixture (p- and n-type) was hot pressed. The X-ray diffraction (XRD) patterns, shown FIG. 3, indicate that both the hexagonal nickel and rhombohedral Bi₂Te₃-based materials were present in the reactant product, plus another phase that matches well with those of NiTe shown in FIG. 3.

Referring to FIG. 3, the NiTe bulk was made by ball milling and hot pressing, in contrast to a conventional sputtering method. Furthermore, it is noted that the major impurity peaks in Ni/Bi_{0.4}Sb_{1.6}Te₃ have a slight larger 2θ than that of Bi₂Te_{2.7}Se_{0.3}. Further analysis of the XRD pattern of Bi₂Te_{2.7}Se_{0.3} shows that the impurity phase is more close to Ni₂SbTe, which has a similar hexagonal crystalline structure (P63/mmc, No. 194) with NiTe, but with Sb and Te sharing the same atomic site in the corresponding crystal structure. According to the chemical composition of the IRL of Ni/Bi_{0.4}Sb_{1.6}Te₃ interface, Bi₂Te_{2.7}Se_{0.3}, the impurity phase should be NiTe₁₋ₓSbₓ. In other words, both Te and Sb from Bi_{0.4}Sb_{1.6}Te₃ reacted with Ni at the Ni/Bi_{0.4}Sb_{1.6}Te₃ interface, explaining no obvious Te deficiency in Bi_{0.4}Sb_{1.6}Te₃ shown in FIG. 2A, but a significant Te deficiency in Bi₂Te_{2.7}Se_{0.3} as shown in FIG. 2B, as shown by the differing striations between FIGS. 2A and 2B.

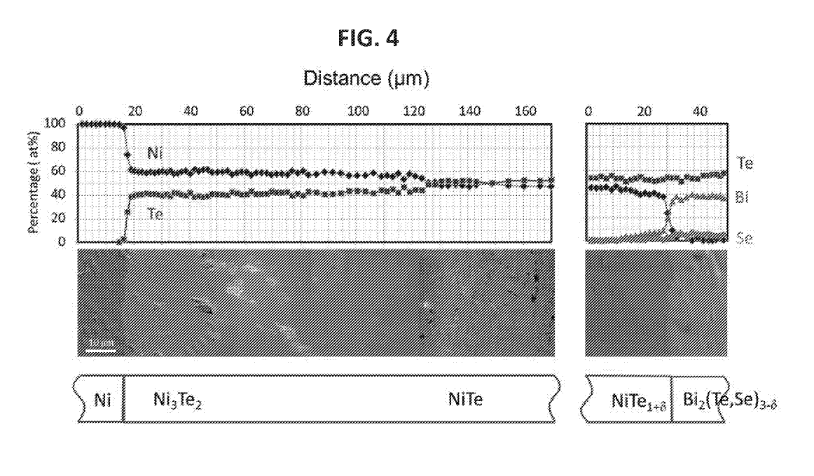

Referring now to FIG. 4, in an embodiment, NiTe was synthesized by ball milling and disposed between Ni and Bi₂Te_{2.7}Se_{0.3} to form a new layer structure, i.e., Ni/NiTe/Bi₂Te_{2.7}Se_{0.3}/NiTe/Ni, in order to determine whether the Ni₃Te₂ phase forms at the interface. The thickness of the Ni-layer was varied between about 0.2 and about 1.5 mm for Ni deposited on NiTe and Bi₂Te_{2.7}Se_{0.3}, respectively. After hot pressing, a new layer of Ni₃Te₂ was clearly formed according to the reaction: Ni+NiTe→Ni₃Te₂. The thickness of the newly formed Ni₃Te₂ is about 100 μm.

As shown in FIG. 4, at the interface between NiTe and Bi₂Te_{2.7}Se_{0.3}, significant diffusion of Te from Bi₂Te_{2.7}Se_{0.3} into the NiTe layer occurred according to: NiTe+Bi₂(Te, Se)₃→NiTe_{1+δ}+Bi₂(Te, Se)_{3-δ}, causing a Te deficiency in Bi₂Te_{2.7}Se_{0.3}. Thus, the NiTe layer may be effective in some but not all applications effective barrier layer to block the diffusion of Ni into the thermoelectric materials, which may be the reason for the efficiency degradation due to the unstable interface. Diffusion of Ni in the Bi₂Te₃-based materials was also observed, in some embodiments an “abnormally” high concentration of Ni (2˜7%) even 10˜20 μm away from the interface reaction layer (IRL) was noted.

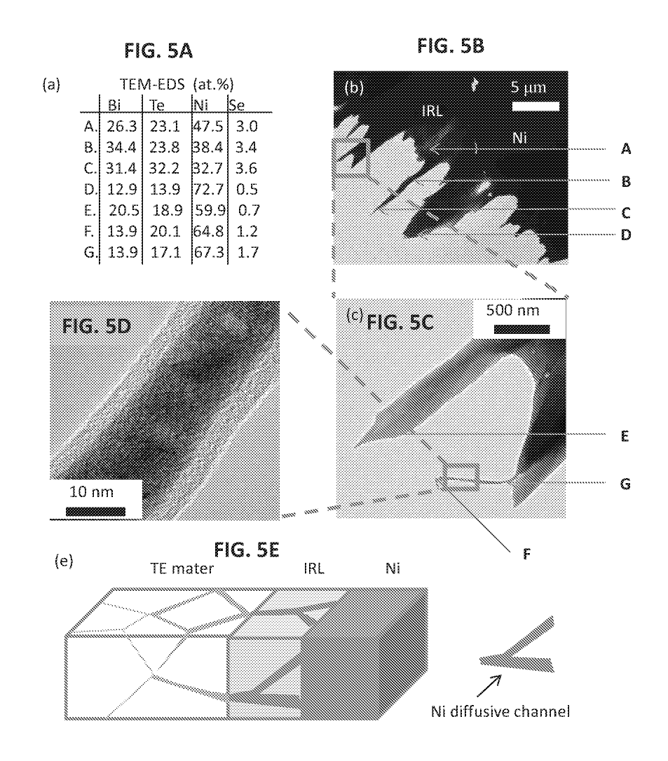

Turning to FIGS. 5A-5E shows the TEM images and EDS compositions of selected points at the Ni/Bi₂Te_{2.7}Se_{0.3} interface. The thickness reduction was achieved from the thermoelectric material side slowly approaching the Ni side in the preparation of TEM sample. A boundary between the thermoelectric material and the IRL, characterized with some holes, are clearly seen from FIG. 5B. One special feature was the sharp tips near the Ni/Bi₂Te_{2.7}Se_{0.3} interface in the thermoelectric material side. The TEM-EDS suggested that most of this sharp tip composed of “abnormally” high concentration of Ni (>50 at. %), which was summarized in FIG. 5A. FIG. 5C is a TEM image of an IRL taken from the square area as indicated from 5B, and FIG. 5D is taken from between point F and point G of FIG. 5C at 50× less magnification than FIG. 5C. A near pure Ni needle was found, as shown in FIG. 5B and identified from points B to C, which could be a direct evidence of the fast diffusion of Ni along the Bi₂Te_{2.7}Se_{0.3} grain boundary. “A” denotes the interface phase. A schematic model for the diffusion of Ni into Bi₂Te_{2.7}Se_{0.3} was shown in FIG. 5E. One possible explanation is that residual Ni is left at the interface during the thickness reduction process of the TEM sample because Ni has a higher hardness than Bi₂Te_{2.7}Se_{0.3}. The undesirable high contact resistance in n-type Ni/Bi₂Te_{2.7}Se_{0.3}/Ni legs made by direct hot pressing may be attributable to 1) the poor electrical conductivity of the new reaction product, 2) the Te-deficient region, and 3) the carrier concentration change due to Ni diffusion into Bi₂Te_{2.7}Se_{0.3}.

Effect of the New Reaction Product

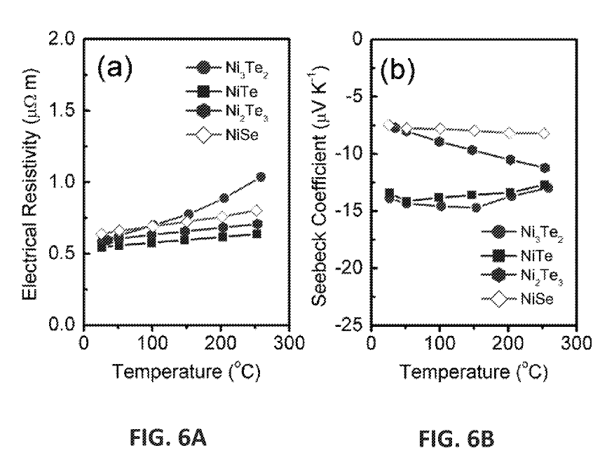

A plurality of phases of NiSe, Ni₂Te₃, and Ni₃Te₂ were fabricated according to the Ni—Se and Ni—Te phase diagram by the high-energy ball milling and hot pressing method disclosed herein. Referring now to FIGS. 6A and 6B, the fabricated samples show a metal-like behavior in FIG. 6A with low electrical resistivity (from about 0.5 μΩ m to about 0.6 μΩ m), which is slightly higher than that of hot pressed Ni at 500° C. (0.15 μΩ m, density=6.2 g cm⁻³), but lower than that of Bi₂Te_{2.7}Se_{0.3} (about 10 μΩ m). Therefore, the high contact resistance illustrated in FIGS. 6A and 6B cannot be from the resistance of these reaction products. Furthermore, all the samples show a negative Seebeck coefficient as illustrated in FIG. 6B (−5 to −15 μV K⁻¹), of the same type as Bi₂Te_{2.7}Se_{0.3}.

Se/Te-Deficient Bi₂(Te_{0.9}Se_{0.1})_{3-δ}

The intrinsic defects, such as vacancy and anti-site defect, in the rhombohedral structure M₂X₃ type compounds may be employed to determine the electrical transport properties. In an embodiment, M may comprise Sb, Bi, or alloys or combinations thereof, and X may comprise Te, Se, S, or alloys and combinations thereof. Since a Te-deficient region was observed at the thermoelectric material side in the Ni/Bi₂Te_{2.7}Se_{0.3} interface (FIG. 2B), the possible defects that impact the electrical transport properties may be near the contact interface. For example, in a single crystal, the formation of metal anti-site defect Mₓ would be more energy-favorable than chalcogen vacancy V_{X} in the chalcogen-deficient Bi₂Te_{3-δ}. The substitution of Bi with Sb would enhance the formation of Mₓ but suppress V_{X}, leading to more p-type behavior. However, the replacement of Te with Se decreases the concentration of Mₓ and increases that of V_{X}, resulting in more n-type behavior.

In an embodiment in polycrystalline M₂X₃, the dangling bonding due to missing chalcogen X behaves as partial V_{X}. As a result, most Bi₂Te₃ and Bi₂Te₃₋ₓSeₓ polycrystals show a negative Seebeck coefficient.

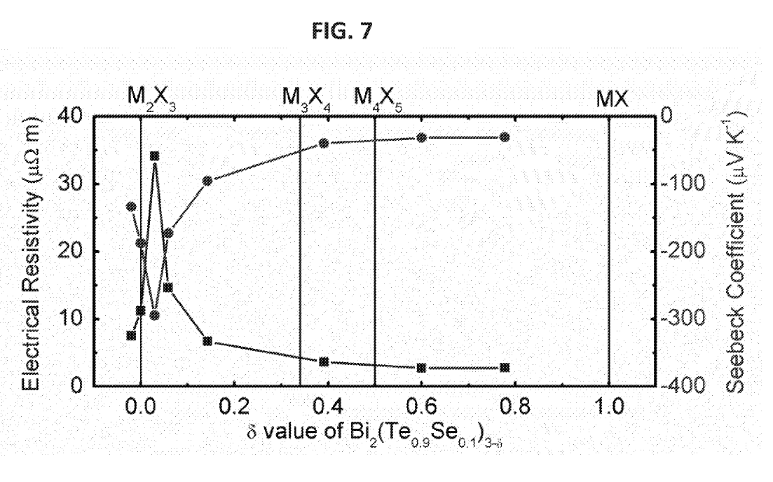

Referring now to FIG. 7, when the M/X ratio is slightly deviated from stoichiometric value of ⅔ by δ (δ<0.03), an increased electrical resistivity and Seebeck coefficient is seen in Bi₂(Te_{0.9}Se_{0.1})_{3-δ}. However, the electrical resistivity drops from about 34 μΩ m to about 14 μΩ m as the M/X ratio changes from about δ=0.04 to about δ=0.06. The high resistivity may be due to the slight deviation from stoichiometric ratio and may contribute to the high contact resistance that was observed.

Nickel Doping Effect

As shown herein, nickel (Ni) diffused into the Bi₂Te₃-based thermoelectric element can act as a dopant to affect the electrical transport properties. The most favorable atomic site for Ni in the Bi₂Te₃-type crystalline structure is discussed herein. In order to consider all the possibilities, including interstitial (Niᵢ), and substitution at metallic site (Ni_{M}) and chalcogen site (Ni_{X}) in the M₂X₃ lattice, 1 at. % nickel was added into three Bi₂Te₃-based compounds: Ni_{0.01}Bi₂Te_{2.7}Se_{0.3}, Ni_{0.01}Bi_{1.99}Te_{2.7}Se_{0.3}, Bi₂Te_{2.7}Se_{0.29}Ni_{0.01}. All the samples were made by ball milling and hot pressing.

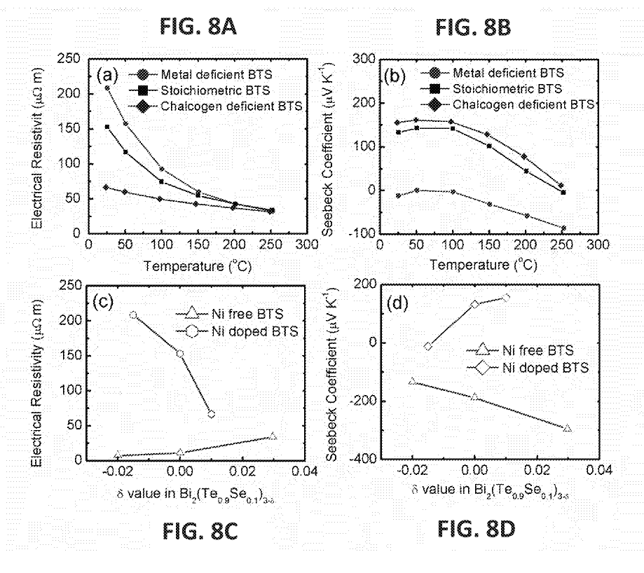

Referring now to FIGS. 8A-8D, all three Ni containing samples show a high electrical resistivity (60˜210 μΩ m) near room temperature, which is much higher than those of the nickel-free samples made by the same fabrication condition as shown in FIG. 8C. Furthermore, a positive Seebeck coefficient was seen in both Ni_{0.01}Bi₂Te_{2.7}Se_{0.3} and Bi₂Te_{2.7}Se_{0.29}Ni_{0.01}, which is in contrast to the normal negative Seebeck coefficient in Bi₂(Te_{0.9}Se_{0.1})_{3-δ} materials, as shown in FIG. 8D. In other words, Ni is a strong acceptor in this case. In order to get more information about the combined effect of the Ni doping and Te deficiency, more compositions in a map of χ and δ, according to the formula of (Bi₁₋ₓNiₓ)₂(Te, Se)_{3-δ}, were evaluated. FIGS. 8A and 8B illustrate the electrical resistivity and Seebeck coefficient, respectively, of the metal deficient, stoichiometric, and chalcogen deficient samples, with all samples having a similar electrical resistivity (FIG. 8A) at about 250° C. The Seebeck coefficient was observed as shown in FIG. 8B and was the highest for the chalcogen deficient sample and the lowest for the metal deficient sample.

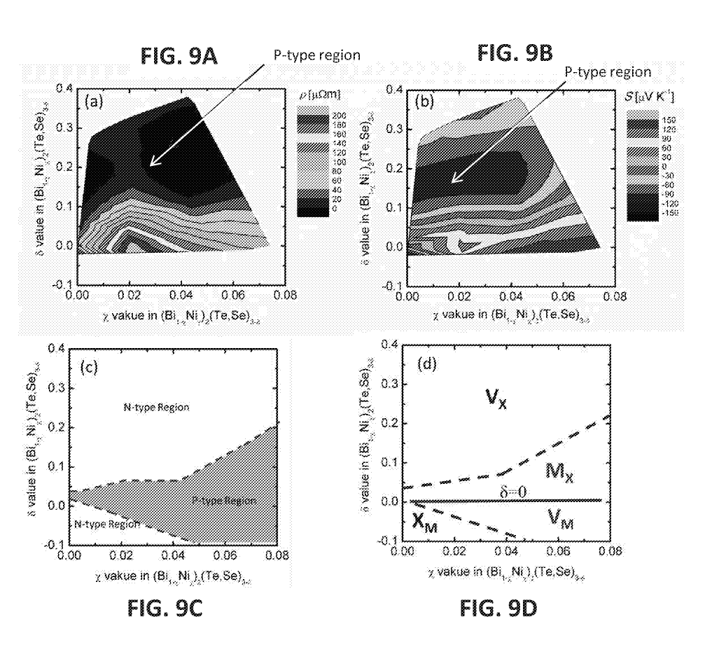

Referring now to FIGS. 9A-9D, contour maps of electrical resistivity (FIG. 9A) and the Seebeck coefficient (FIG. 9B), and graphs of the major carriers (FIG. 9C) and the major defect (FIG. 9D) are presented as a function of composition and illustrate the impact of Ni content on thermoelectric properties. FIG. 9A shows the contour map of electrical resistivity and FIG. 9B illustrates Seebeck coefficient for the (Bi₁₋ₓNiₓ)₂(Te, Se)_{3-δ} system at room temperature, each of FIGS. 9A and 9B were built on 16 samples. FIGS. 9A and 9B illustrate a p-type region, corresponding to high resistivity. A very narrow p-type gap in chalcogen-deficiency (δ value) was seen in the Ni-free polycrystalline Bi₂(Te, Se)_{3-δ}. However, the p-type composition gap (δ value) significantly widens with increased nickel concentration as shown in FIG. 9C. As discussed herein, the type of major carrier for (Bi₁₋ₓNiₓ)₂(Te, Se)_{3-δ} is a result of the competition between the metal antisite defect M_{X} and the chalcogen vacancy V_{X}. In the Ni-free case, M_{X} is dominant in a slightly chalcogen deficient sample, while V_{X} becomes dominant when the chalcogen deficiency is increased as illustrated in FIG. 9D. In the Ni-containing embodiment, Ni plays a similar role with Bi as cation in the M₂X₃ (M=Bi, Ni and X=Te, Se) structure. The formation energy of Niₓ could be even lower than Bi_{X} (X=Te, Se), explaining why a larger δ reverses the dominant defect from M_{X} to V_{X}, and hence a wider p-type composition region in δ value was seen in Ni containing (Bi₁₋ₓNiₓ)₂(Te, Se)_{3-δ}. It is clear that the high contact resistance in n-type Ni/Bi₂Te_{2.7}Se_{0.3}/Ni is caused by this highly resistive p-type composition region (PTR) due to Ni getting into the X-site and the chalcogen-deficiency. Regarding the diffusion of Ni into thermoelectric materials, the Vₓ due to chalcogen transferring towards the reaction interface could be another channel besides the grain boundary channel, and finally form some p-type defect Ni_{X}. Although the formation of Niₓ would neutralize the negative charged carrier and raise the electrical resistivity in n-type legs, it increases the positive charged carrier and reduces electrical resistivity in p-type legs. As such, the high contact resistance in n-type legs is typically observed only in n-type legs and not in p-type legs.

The Direct Evidence for the High R_{c}

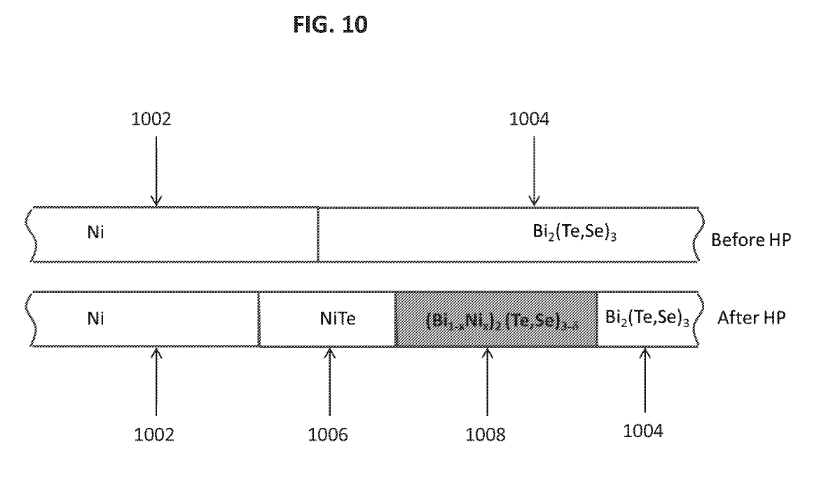

Referring to FIG. 10, a schematic figure to explain the high contact resistance observed the probe scanning measurement. Prior to hot-pressing, there were two regions 1002 and 1004, where region 1002 comprises Ni and region 1004 comprises Bi₂(Te,Se)₃. After hot-pressing, the sample additionally comprises two regions formed during hot-pressing, a region 1006 comprising NiTe and a region 1008 of (Bi₁₋ₓNiₓ)₂(Te,Se)_{3-δ} with the Ni dopant. In some embodiments, a chalcogen deficiency may contribute to the high contact resistance.

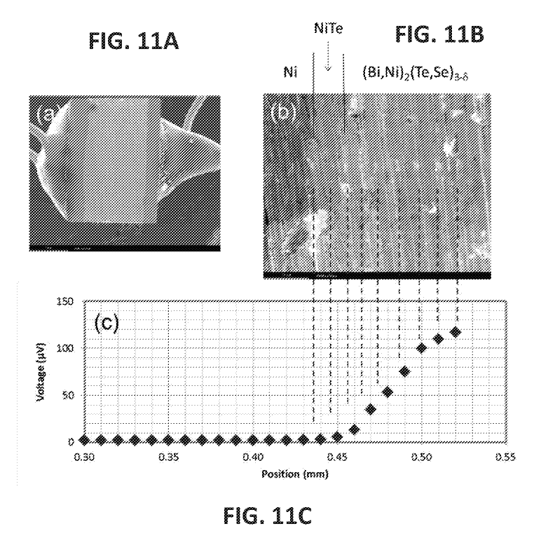

Referring to FIG. 11A, an image that shows the SEM of the sample WS-CTN-16-2 (Alloy12/WS-Hui4# powder, hot pressed at 500° C.) after probe scanning measurement, the imprinted marks left by the probe used to detect the high Rc region are illustrated in FIG. 11B, and the voltage configuration of the probe is illustrated in FIG. 11C. In order to identify the exactly location of the high Rc region, probe scanning was conducted from Ni to TE materials, and stopped the scanning when the voltage jumping is finished. This confirms the model in FIG. 10 is accurate.

Introduction of a Barrier to Prevent Formation of the p-Type Region

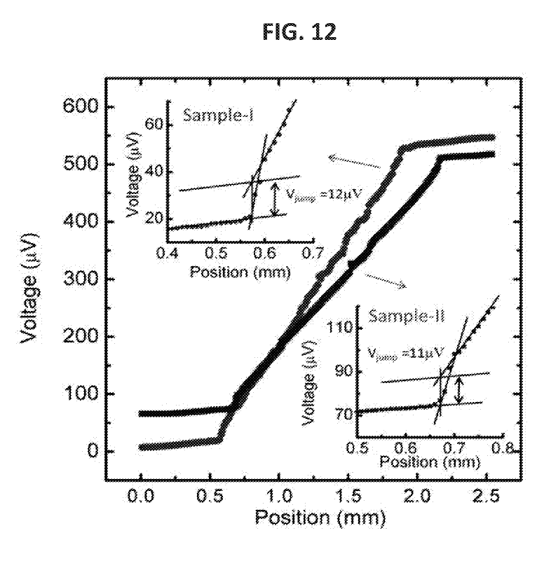

In an embodiment, in order to prevent the formation of the p-type region (PTR) within the Bi₂Te₃-based thermoelectric element, two interlayers were disposed between Ni and Bi₂Te_{2.7}Se_{0.3}, to form a sandwich structure that may be a stacked/layered structure i.e., Ni/Ni₃Te₂/Ni₂Te₃/Bi₂Te_{2.7}Se_{0.3}/Ni₂Te₃/Ni₃Te₂/Ni, and hot pressed at 500° C. Turning to FIG. 12, the contact resistance of the structure Ni/Ni₃Te₂/Ni₂Te₃/Bi₂Te_{2.7}Se_{0.3}/Ni₂Te₃/Ni₃Te₂/Ni is only about 4 μΩ cm², much lower but still may not be employed for some applications of thermoelectric materials.

In order to balance the contact resistance and the bonding strength, degree interface reaction was allowed without causing the formation of tellurium deficient region (TDR). NiSe₂ has a melting point of 856° C., which is higher than that of Se, Te, and TeO₂. A barrier layer (BL) made of 90% Bi₂Te_{2.7}Se_{0.3}+10% NiSe₂ (referred to herein as “BL-1”) was tried and achieved a balanced bonding strength (16 MPa) and contact resistance (9 μΩ cm²) in the layered structure Ni/BL-1/Bi₂Te_{2.7}Se_{0.3}/BL-1/Ni, hot pressed at 425° C. While one example of a BL-1 layer is provided herein, other embodiments may comprise a barrier layer according to a formula of: Bi2Te2.7Se0.3+x % DQ, x=0.5-20, where DQ comprises at least one of NiSe, NiSe₂, FeSe, FeSe₂, CoSe, CoSe₂.

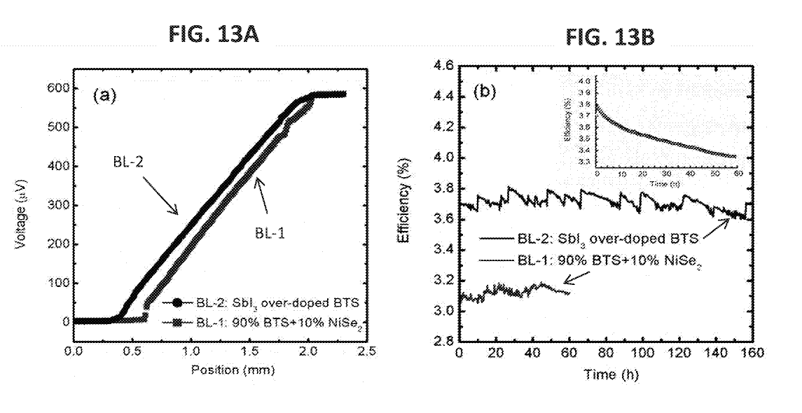

In an alternate embodiment, Bi₂Te_{2.7}Se_{0.3} was over-doped with 1% SbI₃ (p<5 μΩ m) as the barrier layer, as shown in FIGS. 13A and 13B. No voltage jump was seen in the scanning voltage probe, i.e., no significant contact resistance in FIG. 13A (<1μΩ cm²). The acceptor related to Ni_{Te} and Bi_{Te} defects could not create a p-type region due to its high n-type carrier provided by iodine. Furthermore, this hot pressed contact interface also shows enhanced bonding strength of 16 MPa as compared with that made by certain sputtering or electro-deposition methods (<10 MPa). The efficiency measurement in FIG. 13B shows that the quite stable efficiency over 150h without notable efficiency degradation, which is in contrast to the obvious efficiency degradation in the sample with regular Ni as the metallization layer without barrier layer. Furthermore, the sample with barrier layer survived after the thermal cycles test.

A carrier layer with a high carrier concentration, such as BL-2, can effectively reduce the contact resistance. Various embodiments may be fabricated, including embodiments comprising layers as in a first embodiment Ni/BL-1/Bi₂Te_{2.7}Se_{0.3}/BL-1/Ni and in a second embodiment, Ni/BL-2/Bi₂Te_{2.7}Se_{0.3}/BL-2/Ni, which is made by hot pressing at 425° C. BL-1: 90% Bi₂Te_{2.7}Se_{0.3}+10% NiSe₂, BL-2: 1% SbI₃ doped Bi₂Te_{2.7}Se_{0.3}.

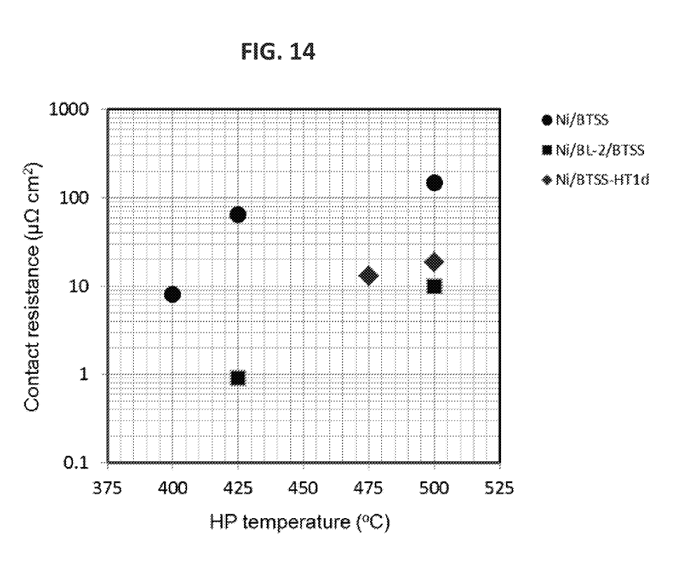

In an embodiment, the total thickness of the BL-2 layer is about 0.6 mm. In alternate embodiments, the thickness may be less than about 0.6 mm. In some embodiments, the BL-1 layer discussed herein may range from about 0.1 mm to about 1.0 mm. As used herein, a “BL-2 layer comprises 1% SbI₃ doped Bi₂Te_{2.7}Se_{0.3}, in contrast to BL-1 which comprises 90% Bi₂Te_{2.7}Se_{0.3}+10% NiSe₂. In an embodiment as illustrated in FIG. 14, the Bi₂Te_{2.7}Se_{0.3}S_{0.01} hot-pressed disc was annealed in an iodine vapor at 150° C. for about one day (Ni/BTSS-HT-1d) and got slightly higher contact resistance as compared with sample Ni/BL-2/BTSS with a barrier layer. In alternate embodiments, the BL-2 layer may be according to the formula BL-2: Bi₂Te_{2.7}Se_{0.3}+y % DY, where y is from about 0.01 to about 3.0 and where DY comprises one of SbI₃, BiI₃, SbBr₃, BiBr₃, SbCl₃, BiCl₃, I₂, Br₂, Cl₂.

Fabrication of a New Contact Material

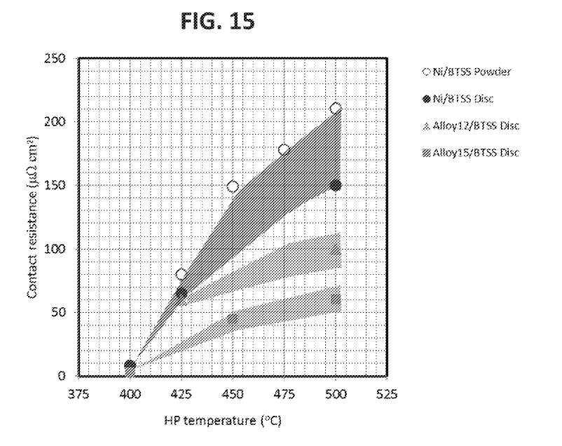

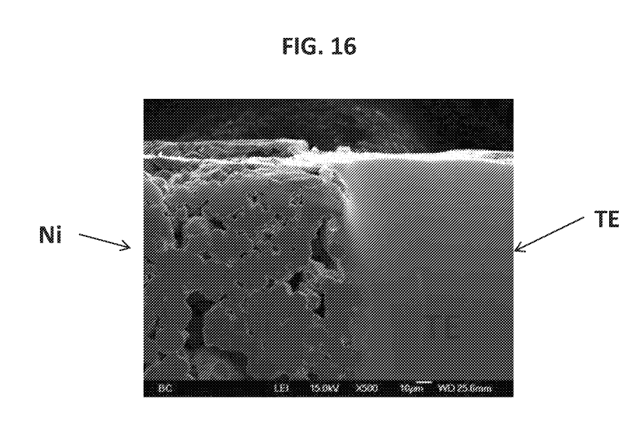

A plurality of alloys were fabricated, two of which are referred to herein as Alloy12 and Alloy15. The alloys exhibited promising lower contact resistance as compared with the pure Ni as shown in FIG. 16. In particular, FIG. 15 illustrates the contact resistance as a function of the hot pressing temperature for Ni/BTSS, Alloy12/BTSS, and Alloy15/BTSS. BTSS: Bi₂Te_{2.7}Se_{0.3}S_{0.01}. Alloy12 is according to a formula A_{δ1}B_{δ2}C_{δ3}, in one example, δ1 comprises 87 at. %, δ2 comprises about 4 at. %, and δ3 comprises about 9 at. %. In one embodiment, Alloy15 is according to the formula A_{δ1}B_{δ2}C_{δ3}D_{δ4}, in one example, δ1 comprises about 82 at. %, δ2 comprises about 4 at. %, δ3 comprises about 8 at. %, and δ4 comprises about 4 at. %. In both Alloy12 and Alloy15, A comprises Ni, B may comprise Cr, Fe, Co, as well as alloys and combinations thereof; C comprises S, Se, Te, Cl, Br, I, as well as alloys and combinations thereof, and in Alloy15 D may comprise Al, Ga, In, Cu, Ag, Au as well as alloys and combinations thereof. As shown in FIG. 15, the contact resistance is also reduced as the hot pressing temperature is reduced with a cost of the reduced bonding strength. As an example, the bonding strength of the contact sample with a pure Ni is decreased from 22 MPa to 16 MPa as the hot pressing temperature is decreased from 500° C. If the hot pressing temperature is reduced down to 400° C., the contact resistance may be lower than about 10 μΩ cm², and in some embodiments may be even closer to about 1 Ω cm², providing that the bonding strength is not compromised.

Referring to FIG. 16, the SEM image of the contact sample with pure Ni hot pressed at 400° C., the low density of the Ni layer (as indicated by the porosity) could be one of the reasons for the weak bonding strength. The density of pure Ni hot pressed at 400° C. is ˜6 g cm⁻³, with a relative density less than 70%, which is too low for some applications. One of the advantages of the alloy systems fabricated herein is improved density, which could be expected to have a stronger bonding strength. In contract, the density of Alloy15 hot pressed at 400° C. is 6.8 g cm⁻³, with a relative density less than 86%.

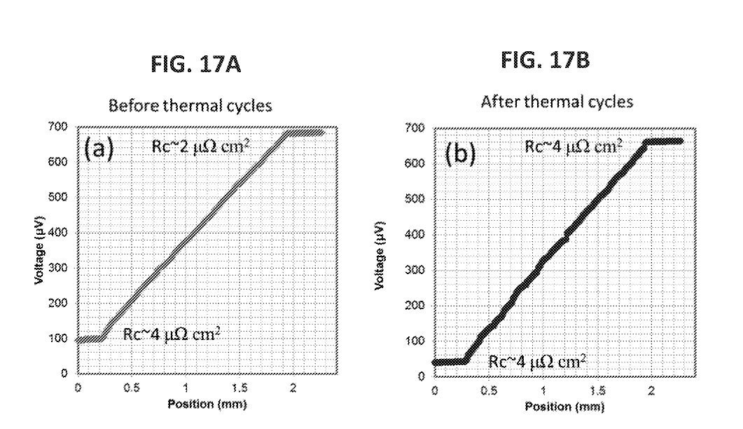

FIGS. 17A and 17B illustrate the contact resistance (Rc) before and after 12 thermal cycles. FIGS. 17A and 17B were obtained for Alloy15/BTSS hot pressed at 400° C. BTSS=Bi₂Te_{2.7}Se_{0.3}S_{0.01}. Alloy15 is according to the formula A_{δ1}B_{δ2}C_{δ3}D_{δ4}, where A comprises Ni, B may comprise Cr, Fe, Co, as well as alloys and combinations thereof; C comprises S, Se, Te, Cl, Br, I, as well as alloys and combinations thereof, and in Alloy15 D may comprise Al, Ga, In, Cu, Ag, Au as well as alloys and combinations thereof. The test was performed after 12 thermal cycles for the contact sample with Alloy15, which was hot pressed at 400° C. and the measurements before (FIG. 17A) and after (FIG. 17B) the 12 thermal cycles. In an embodiment, a single thermal cycle comprises: heating from 25° C. to 250° C. at 300° C./hour, and holding at 250° C. for 1 hour, and cooling down from 250° C. to 25° C. at 500° C./hour, and holding at 25° C. for 1 hour. FIG. 17B shows that the contact sample with Alloy15 as the metal layer shows no notable changes after the thermal cycles.

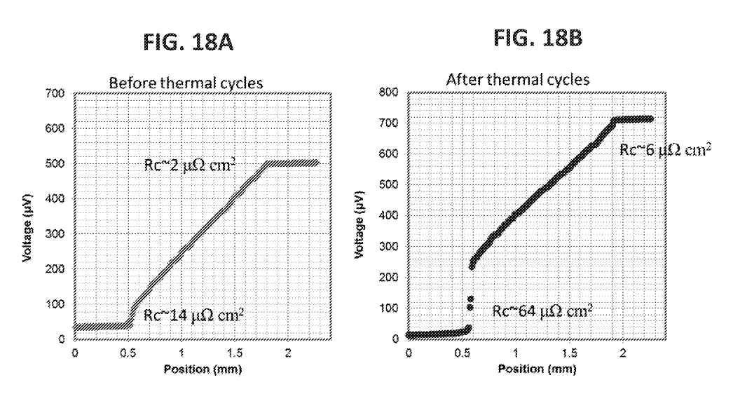

FIGS. 18A and 18B illustrate the contact resistance (Rc) before and after 12 thermal cycles for Ni/BTSS hot pressed at 400° C. where BTSS=Bi₂Te_{2.7}Se_{0.3}S_{0.01}). In contrast to FIGS. 17A and 17B, the contact sample with pure Ni as the metal layer as shown in FIG. 18B after being subject 12 thermal cycles under the same conditions as the samples in FIG. 17B shows increase in the contact resistance at both sides, i.e. from 2 to 6 μΩ cm² for one side and from 14 to 64 μΩ cm² for another side. It is clear shown that the new alloys show the promising to solve the contact problem of n-type Bi₂Te_{2.7}Se_{0.3}. FIG. 18A illustrates the contact resistance prior to the 12 cycles.

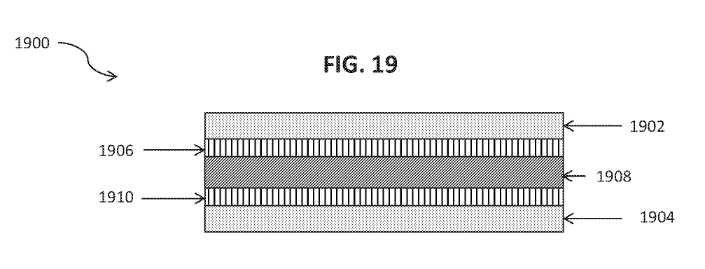

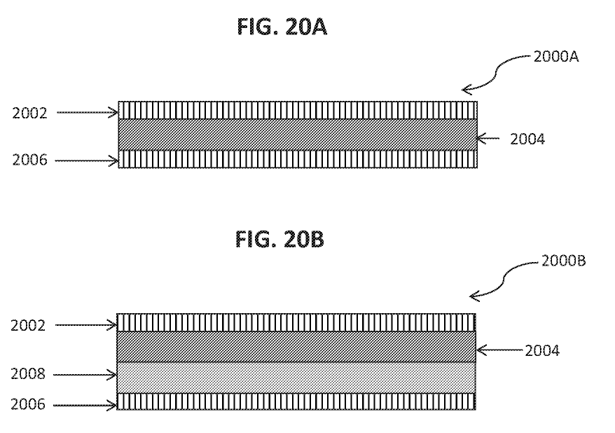

FIG. 19 is an illustration of a first embodiment of a thermoelectric leg. In cross-section 1900, it is appreciated that the layers/components are illustrated as being of varying thicknesses and shades/patterns and that the actual thickness and comparative thicknesses of each layer in FIG. 19 and in FIG. 20 as discussed below may vary according to the composition of the components as well as the desired properties for the device for a particular application. The cross-section 1900 comprises a first metallic layer 1902 in contact with a first interlayer 1906. A thermoelectric material that may comprise an n-type thermoelectric material 1908 is in contact with the first interlayer 1906 and a second interlayer 1910. The second interlayer 1910 is in contact with a second metallic layer 1904. In an embodiment, the first and the second interlayers 1906 and 1910 may comprise the same material, and in alternate embodiments each layer 1906 and 1910 may comprise different materials. In an embodiment, the first metallic layer 1902 and the second metallic layer 1904 may comprise nickel (Ni), and the first interlayer 1906 and/or the second interlayer 1910 may comprise a material according to the formula, Bi₂Te_{2.7}Se_{0.3}+x % DQ, where x is from about 0.5 to about 20, and where DQ comprises at least one of NiSe, NiSe₂, FeSe, FeSe₂, CoSe, CoSe₂, as well as alloys and combinations thereof. In an alternate embodiment, the first interlayer 1906 and/or the second interlayer 1910 may comprise a material according to the formula Bi₂Te_{2.7}Se_{0.3}+y % DY, where y is from about 0.01 to about 3 and where DY comprises at least one of SbI₃, BiI₃, SbBr₃, BiBr₃, SbCl₃, BiCl₃, I₂, Br₂, Cl₂, and combinations thereof.

FIG. 20A illustrates cross-section 2000A of a thermoelectric leg. It is appreciated that, in FIGS. 20A and 20B, the relative thickness and shading are employed for illustrative purposes and that the actual thicknesses, alone and in combination to create an overall thickness, may vary depending upon the materials used and the end application's functionality. In cross-section 2000A, a first metallic layer 2002 is in contact with a first thermoelectric layer 2004, and the first thermoelectric layer 2004 is in contact with a second metallic layer. In an embodiment, the thermoelectric layer 2004 may comprise a BiTe-based material, for example Bi_{A}Te_{B}Se_{C}S_{D} or Bi₂Te_{2.7}Se_{0.3}S_{0.01}. The first and the second metallic layers 2002 and 2006 may comprise the same or different materials, in one embodiment, at least one of 2002 and 2006 comprises a material according to the formula A_{δ1}B_{δ2}C_{δ3}, where A comprises Ni, B may comprise Cr, Fe, Co, as well as alloys and combinations thereof; C comprises S, Se, Te, Cl, Br, I, as well as alloys and combinations thereof, and wherein δ1 is from about 80% to about 90%, wherein δ2 is from about 1 to about 10%, wherein δ3 is from about 5% to about 15%

In an alternate embodiment, at least one of 2002 and 2006 comprises a material according to the formula A_{δ1}B_{δ2}C_{δ3}D_{δ4}, where A comprises Ni, B may comprise Cr, Fe, Co, as well as alloys and combinations thereof; C comprises S, Se, Te, Cl, Br, I, as well as alloys and combinations thereof, and D may comprise Al, Ga, In, Cu, Ag, Au, as well as alloys and combinations thereof. In an embodiment, δ1 is from about 70% to about 90%, wherein δ2 is from about 1% to about 90%, wherein δ3 is from about 5% to about 15%, wherein δ4 is from about 5% to about 10%

FIG. 20B is an alternate embodiment of a cross-section 2000B of a thermoelectric leg that may comprise layers 2002, 2004, and 2006 similar to those discussed in FIG. 20A. However, in FIG. 20B, cross-section 2000B comprises the first metallic layer 2002 is in contact with the first thermoelectric layer 2004, and the first thermoelectric layer 2004 is in contact with the second thermoelectric layer 2008, which is also in contact with the second metallic layer 2006. The two thermoelectric layers 2004 and 2008 may comprise the same, similar (overlapping elements), or different materials, depending upon the embodiment. The method of manufacture of the thermoelectric legs in FIGS. 19, 20A, and 20B may comprise ball-milling or otherwise reducing the components to a predetermined particle size, and then hot-pressing the components in one or more hot-pressing cycles from about 250° C. to about 600° C.

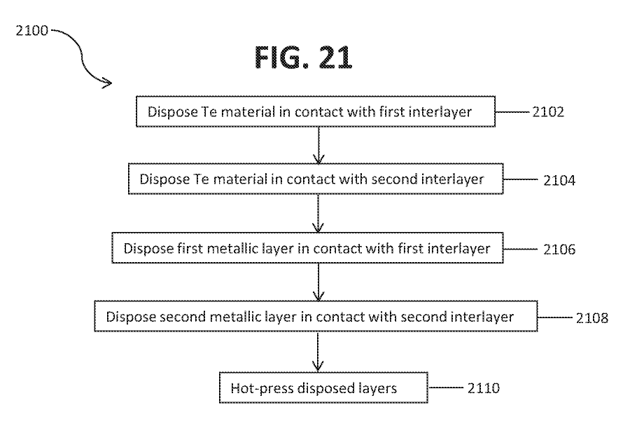

FIG. 21 is a method 2100 of fabricating thermoelectric devices. At block 2102, an n-type thermoelectric material (TE material) is disposed in contact with a first interlayer and at block 2104 the TE material is disposed in contact with a second interlayer. The n-type thermoelectric material comprises a first side and a second side, where the first side is in contact with the first interlayer and the second side is in contact with the second interlayer. At block 2106, a first metallic layer is disposed in contact with the first interlayer, and at block 2108, a second metallic layer may be disposed in contact with the second interlayer. The components disposed at blocks 2102-2108 in contact with each other may all be in powder form, in which case they are hot-pressed at block 2110. In alternate embodiments, prior to being disposed in contact with the first interlayer and second interlayer at blocks 2102 and 2104, the TE material is fabricated by milling and hot-pressing as discussed herein. In this embodiment, subsequent to the remaining components being disposed, the interlayers, metallic layers, and TE material are hot-pressed at block 2110. In an embodiment, the first metallic layer and the second metallic layer 1904 may comprise nickel (Ni), and the first interlayer and/or the second interlayer may comprise a material according to the formula, Bi₂Te_{2.7}Se_{0.3}+x % DQ, where x is from about 0.5 to about 20, and where DQ comprises at least one of NiSe, NiSe₂, FeSe, FeSe₂, CoSe, CoSe₂, as well as alloys and combinations thereof. In an alternate embodiment, the first interlayer and/or the second interlayer may comprise a material according to the formula Bi₂Te_{2.7}Se_{0.3}+y % DY, where y is from about 0.01 to about 3 and where DY comprises at least one of SbI₃, BiI₃, SbBr₃, BiBr₃, SbCl₃, BiCl₃, I₂, Br₂, Cl₂, and combinations thereof.

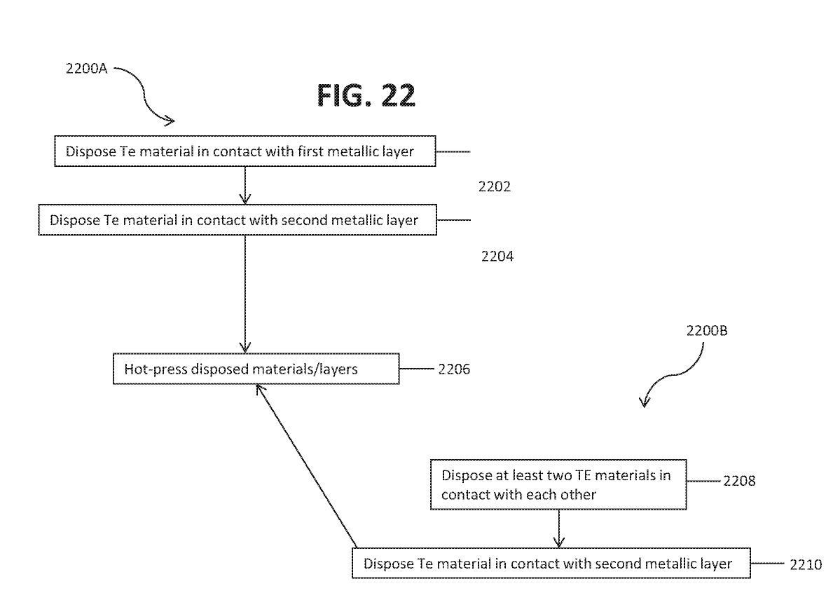

FIG. 22 is a flow chart of other methods 2200A and 2200B of fabricating thermoelectric devices. In the method 2200A at block 2202, a thermoelectric material may be disposed in contact with a first metallic layer, where the TE material comprises a first side and a second side and the first side is disposed in contact with the first metallic layer. At block 2204, a second metallic layer is disposed in contact with the second side of the TE material. In an embodiment, no interlayers may be employed. In some embodiments, as discussed in method 2100 in FIG. 21, the components disposed at blocks 2202-2204 in contact with each other may all be in powder form, in which case they are hot-pressed at block 2206. In alternate embodiments, prior to being disposed in contact with the first and second metallic layers at blocks 2e02 and 2e04, the TE material is fabricated by milling and hot-pressing as discussed herein. In this embodiment, subsequent to the remaining components being disposed in contact with the previously-pressed TE material, the interlayers, metallic layers, and TE material are hot-pressed at block 2206. In an embodiment, the TE material may comprise a BiTe-based material, for example Bi_{A}Te_{B}Se_{C}S_{D} or Bi₂Te_{2.7}Se_{0.3}S_{0.01}. The first and the second metallic layers may comprise the same or different materials, in one embodiment, at least one which comprises a material according to the formula A_{δ1}B_{δ2}C_{δ3}, where A comprises Ni, B may comprise Cr, Fe, Co, as well as alloys and combinations thereof; C comprises S, Se, Te, Cl, Br, I, as well as alloys and combinations thereof, and wherein δ1 is from about 80% to about 90%, wherein δ2 is from about 1 to about 10%, wherein δ3 is from about 5% to about 15%. In an alternate embodiment, at least one the first and the second metallic layers comprises a material according to the formula A_{δ1}B_{δ2}C_{δ3}D_{δ4}, where A comprises Ni, B may comprise Cr, Fe, Co, as well as alloys and combinations thereof; C comprises S, Se, Te, Cl, Br, I, as well as alloys and combinations thereof, and D may comprise Al, Ga, In, Cu, Ag, Au, as well as alloys and combinations thereof. In an embodiment, δ1 is from about 70% to about 90%, wherein δ2 is from about 1% to about 90%, wherein δ3 is from about 5% to about 15%, wherein δ4 is from about 5% to about 10%.

In another embodiment, as shown in method 2200B in FIG. 22, a first thermoelectric material is disposed in contact with a second thermoelectric material at block 2208. The first TE material comprises a first and a second side, as does the second TE material, and the first side of the first TE material may be disposed in contact with the first side of the second TE material. At block 2210, a first metallic layer is disposed in contact with the second side of the first TE material, and at block 2212 a second metallic layer is disposed in contact with the second side of the second TE material. The two thermoelectric layers may comprise the same, similar (overlapping elements), or different materials, depending upon the embodiment. The method of manufacture of the thermoelectric legs may comprise ball-milling or otherwise reducing the components to a predetermined particle size, and then hot-pressing the components in one or more hot-pressing cycles from about 250° C. to about 600° C. As discussed in methods 2200A and 2100 above, the components may be in powdered form at blocks 2208-2212 and hot pressed at block 2206. In other embodiments, one or both of the TE materials may be hot-pressed prior to being disposed in contact with each other and/or the metallic layer(s), which may be powdered, and then hot-pressed at 2206.

Where numerical ranges or limitations are expressly stated, such express ranges or limitations should be understood to include iterative ranges or limitations of like magnitude falling within the expressly stated ranges or limitations (e.g., from about 1 to about 10 includes, 2, 3, 4, etc.; greater than 0.10 includes 0.11, 0.12, 0.13, etc., and in some embodiments may mean that the measured characteristic is within +/−5%, +/−10%, or a stated range). For example, whenever a numerical range with a lower limit, R₁, and an upper limit, Rᵤ, is disclosed, any number falling within the range is specifically disclosed. In particular, the following numbers within the range are specifically disclosed: R=R₁+k*(Rᵤ−R₁), wherein k is a variable ranging from 1 percent to 100 percent with a 1 percent increment, i.e., k is 1 percent, 2 percent, 3 percent, 4 percent, 5 percent, . . . , 50 percent, 51 percent, 52 percent, . . . , 95 percent, 96 percent, 97 percent, 98 percent, 99 percent, or 100 percent. Moreover, any numerical range defined by two R numbers as defined in the above is also specifically disclosed. Use of broader terms such as “comprises,” “includes,” and “having” should be understood to provide support for narrower terms such as “consisting of,” “consisting essentially of,” and “comprised substantially of.” Each and every claim is incorporated into the specification as further disclosure, and the claims are exemplary embodiment(s) of the present invention.

While exemplary embodiments of the invention have been shown and described, modifications thereof can be made by one skilled in the art without departing from the scope or teachings herein. The embodiments described herein are exemplary only and are not limiting. Many variations and modifications of the compositions, systems, apparatus, and processes described herein are possible and are within the scope of the invention. Accordingly, the scope of protection is not limited to the embodiments described herein, but is only limited by the claims that follow, the scope of which shall include all equivalents of the subject matter of the claims. Unless expressly stated otherwise, the steps in a method claim may be performed in any order and with any suitable combination of materials and processing conditions.

1. A thermoelectric device comprising:
a hot-pressed component comprising:
a first metallic layer in contact with a first thermoelectric layer;
a second metallic layer in contact with the first thermoelectric layer;
wherein at least one of a contact resistance between the first metallic layer and the first thermoelectric layer and a contact resistance between the second metallic layer and the first thermoelectric layer is less than about 10 μΩ cm².

2. The device of claim 1, wherein the contact resistance between the first metallic layer and the first thermoelectric layer is less than about 5 μΩ cm².

3. The device of claim 1, wherein the contact resistance between the second metallic layer and the first thermoelectric layer is less than about 5 μΩ cm².

4. The device of claim 1, wherein the contact resistance between the first metallic layer and the first thermoelectric layer is less than about 1 μΩ cm².

5. The device of claim 1, wherein the contact resistance between the second metallic layer and the first thermoelectric layer is less than about 1 μΩ cm².

6. The device of claim 1, wherein the first metallic layer comprises a composition according to a formula A_{δ1}B_{δ2}C_{δ3}.

7. The device of claim 1, wherein the second metallic layer comprises a composition according to a formula A_{δ1}B_{δ2}C_{δ3}.

8. The device of claim 7, wherein the composition of the first metallic layer further comprises D_{δ4}.

9. The device of claim 8, wherein the composition of the second metallic layer further comprises D_{δ4}.

10. The device of claim 6, wherein A comprises Ni, B comprises one of Cr, Fe, Co, and C comprises S, Se, Te, Cl, Br, and I.

11. The device of claim 7, wherein A comprises Ni, B comprises one of Cr, Fe, Co, and C comprises S, Se, Te, Cl, Br, and I.

12. The device of claim 8, wherein D comprises one of Al, Ga, In, Cu, Ag, and Au.

13. The device of claim 9, wherein D comprises one of Al, Ga, In, Cu, Ag, and Au.

14. The device of claim 7, δ1 is from about 70% to about 90%, wherein δ2 is from about 1% to about 90%, wherein δ3 is from about 5% to about 15%.

15. The device of claim 8, δ1 is from about 70% to about 90%, wherein δ2 is from about 1% to about 90%, wherein δ3 is from about 5% to about 15%.

16. The device of claim 9, δ1 is from about 70% to about 90%, wherein δ2 is from about 1% to about 90%, wherein δ3 is from about 5% to about 15%, wherein δ4 is from about 5% to about 10%.

17. The device of claim 1, further comprising a second thermoelectric layer in contact with the first thermoelectric layer and the second metallic layer.

18. The device of claim 10, δ1 is from about 70% to about 90%, wherein δ2 is from about 1% to about 90%, wherein δ3 is from about 5% to about 15%, wherein δ4 is from about 5% to about 10%.

19. The device of claim 1, wherein the first thermoelectric layer comprises Bi₂Te_{2.7}Se_{0.3}S_{0.01}.

20. A thermoelectric device comprising:
a hot-pressed component comprising:
a first metallic layer in contact with a first interlayer;
a thermoelectric layer in contact with the first interlayer and a second interlayer; and
a second metallic layer in contact with the second interlayer, wherein the thermoelectric layer is disposed between the first and the second metallic layers, wherein a first hot pressed contact interface is formed between the thermoelectric layer and the first interlayer and a second hot pressed contact interface is formed between the thermoelectric layer and the second interlayer, and wherein at least one of the first and the second hot pressed contact interfaces comprises a bonding strength of at least 16 MPa.

21. The structure of claim 20, wherein the first interlayer comprises a formula of Bi₂Te_{2.7}Se_{0.3}+y % DY, wherein y is from about 0.01 to about 3.0, and wherein DY comprises one of SbI₃, BiI₃, SbBr₃, BiBr₃, SbCl₃, BiCl₃, I₂, Br₂, Cl₂.

22. The structure of claim 20, wherein the second interlayer comprises a formula of Bi₂Te_{2.7}Se_{0.3}+y % DY, wherein y is from about 0.01 to about 3.0, and wherein DY comprises one of SbI₃, BiI₃, SbBr₃, BiBr₃, SbCl₃, BiCl₃, I₂, Br₂, Cl₂.

23. The structure of claim 20, wherein the first interlayer comprises a formula of Bi₂Te_{2.7}Se_{0.3}+x % DQ, wherein x is from about 0.5 to about 20, and wherein DQ comprises at least one of NiSe, NiSe₂, FeSe, FeSe₂, CoSe, CoSe₂.

24. The structure of claim 20, wherein the second interlayer comprises a formula of Bi₂Te_{2.7}Se_{0.3}+x % DQ, wherein x is from about 0.5 to about 20, and wherein DQ comprises at least one of NiSe, NiSe₂, FeSe, FeSe₂, CoSe, CoSe₂.
